(19) United States
(12) Patent Application Publication
(10) Pub. No.: US 2013/0299981 A1
(43) Pub. Date: Nov. 14, 2013

(54) MOLDING MATERIAL, METHOD OF FABRICATING THE SAME, AND SEMICONDUCTOR DEVICE

(71) Applicant: SAMSUNG ELECTRONICS CO., LTD., Suwon-Si (KR)

(72) Inventor: Du MAOHUA, Suzhou City (CN)

(73) Assignee: SAMSUNG ELECTRONICS CO., LTD., Suwon-Si (KR)

(21) Appl. No.: 13/890,735

(22) Filed: May 9, 2013

(30) Foreign Application Priority Data
May 10, 2012 (CN) 201210142532.X
Mar. 27, 2013 (KR) 10-2013-0033092

(51) Int. Cl. H01L 23/26; H01L 23/29

(52) U.S. Cl. CPC H01L 23/26; H01L 23/295
USPC 257/738; 252/194; 427/222; 438/127

(57) ABSTRACT

A molding material used to fabricate a semiconductor package, a method of fabricating the molding composition, and a semiconductor package obtained by using the molding composition are disclosed. A molding composition includes a molding resin material, a filler, and a water absorption material coated on a surface of the filler, such that an amount of external moisture penetrating into the semiconductor package may be diminished. A semiconductor package includes a substrate, at least one chip mounted on the substrate, a connecting portion electrically connecting the at least one chip and the substrate, and a molding portion encapsulating the at least one chip on the substrate, wherein the molding portion includes a molding composition including a molding resin material, a filler, and a water absorption material coated on a surface of the filler, such that an amount of external moisture penetrating into the semiconductor package may be diminished.

### CROSS-REFERENCE TO RELATED APPLICATIONS

This application claims priority under 35 U.S.C. §119 to Chinese Patent Application No. 2012-10142532.X, filed on May 10, 2012, in the State Intellectual Property Office of the People's Republic of China, and Korean Patent Application No. 10-2013-0033092, filed on Mar. 27, 2013, in the Korean Intellectual Property Office, the disclosures of which are incorporated herein in their entirety by reference.

### BACKGROUND

1. Field

The inventive concepts relate to a molding composition and a semiconductor package, and more particularly, to a molding composition used to fabricate a semiconductor package, a method of fabricating the molding composition, and a semiconductor package obtained by using the molding composition.

2. Description of the Related Art

With the development of information technology, semiconductor packages are increasingly required. When a molding resin material encapsulating a chip in a semiconductor package is formed of an organic material that may be vulnerable to moisture, and thus, performance of the chip may deteriorate as external moisture penetrates into the chip. Specifically, when a defect, such as a void, exists in the chip, moisture may penetrate into the void, thereby deteriorating the performance of the chip.

Common methods for preventing moisture accumulation and/or concentration include encapsulating a semiconductor package in a material with very low water absorption capabilities and/or a material with water repellant properties. However, these materials cannot fully repel and/or prevent moisture from entering the semiconductor package, especially when a void is present. Thus, the common methods cannot fully protect semiconductor packages from moisture concentration and/or accumulation.

### SUMMARY

The inventive concepts provide a molding composition capable of improving a waterproofing property of a semiconductor package by preventing functions of a chip mounted on the semiconductor package from being deteriorated due to external moisture. The inventive concepts also provide a method of fabricating a molding composition capable of improving a waterproofing property of a semiconductor package. The inventive concepts also provide a semiconductor package having an improved waterproofing property.

According to at least one example embodiment of inventive concepts, a molding material may include a molding resin material, a filler in the molding resin material, and a water absorption material coated on a surface of the filler, such that external moisture is prevented from being transferred to a chip of the semiconductor package when the external moisture penetrates into the semiconductor package.

Example embodiments provide that the water absorption material may include one of a synthetic-resin-based material, a cellulose-based material, and a starch-based material.

Example embodiments provide that the water absorption material may be a water absorbing polymer including one of a polyacrylate based polymer, a polyvinyl alcohol based polymer, a vinyl acetate copolymer, and a polyacrylonitrile hydrolyzate.

Example embodiments provide that the filler may be formed of an inorganic material. According to at least one example embodiment, the filler may include at least one of silicon oxide, silicon dioxide, calcium carbonate, magnesium carbonate, magnesia, clay, alumina (Al₂O₃), titania (TiO₂), talc, calcium silicate, antimony oxide, glass fiber, and eucryptite ceramic.

Example embodiments provide that the filler may be formed of an organic material. According to at least one example embodiment, the filler may include at least one of polyethyleneimine, ethyleneglycol, and polyethyleneglycol.

Example embodiments provide that the molding resin material may be epoxy resin.

Example embodiments provide that the epoxy resin may include one of biphenyl epoxy resin, novolac epoxy resin, dicyclopentadienyl epoxy resin, bisphenol epoxy resin, terpene epoxy resin, aralkyl epoxy resin, multi-functional epoxy resin, naphthalene epoxy resin, and halogenated epoxy resin.

Example embodiments provide that a thickness of the water absorption material may be less than 5 micrometer (μm).

According to another example embodiment of the inventive concepts, a method of fabricating a molding material for a semiconductor package includes dipping a filler in a water absorption material that is in a liquid state. The filler is removed from the water absorption material after the water absorption material is adsorbed on a surface of the filler. A thickness of the water absorption material adsorbed on the surface of the filler is controlled. The water absorption material adsorbed on the surface of the filler is dried.

The method may further include stirring the water absorption material in the liquid state to uniformly adsorb the water absorption material on the surface of the filler.

Example embodiments provide that controlling the thickness of the water absorption material may include inserting the filler into a centrifuge and rotating the centrifuge until a desired thickness is obtained.

Example embodiments provide that the molding material may be heated, cured, and molded to form the molding material to a semiconductor package.

According to another example embodiment of inventive concepts, a semiconductor package may include a substrate, a die attach film disposed on the substrate, at least one chip disposed on the substrate and attached to the substrate through the die attach film, a connecting portion electrically connecting the chip and the substrate, a molding material for encapsulating the chip, and connection portion electrically connecting the semiconductor package with an external circuit. The molding material may include a molding resin material, a filler in the molding resin material, and a water absorption material coated on an outer surface of the filler, such that external moisture is prevented from being transferred to the chip when the external moisture penetrates into the semiconductor package.

Example embodiments provide that the filler may be formed of one of an inorganic material and an organic material, and the water absorption material may be formed of a water absorbing polymer.

Example embodiments provide that the molding material may encapsulate at least one of the connecting and the connection portion.

Example embodiments provide that the connection portion may be one of soldering balls, a conductive bump, and a lead grid array (LGA).

Example embodiments provide an integrated circuit device that may include a module substrate, a control chip on the module substrate, and a plurality of semiconductor packages, as described above, on the module substrate.

Example embodiments provide that the filler may be formed of one of an inorganic material and an organic material, and the water absorption material may be formed of a water absorbing polymer.

Example embodiments provide that the connection portion may be one of soldering balls, a conductive bump, and a lead grid array (LGA).

Example embodiments provide that the controller portion and the memory portion may each include a plurality of semiconductor packages stacked on one another.

Example embodiments provide a computing device that may include an input/output device; a communications interface for connecting the computing device to an external device; a controller portion for controlling the computing device; a memory portion for storing data used for controlling the controller portion; and a bus for providing communications between the input/output device, the memory portion, and the communications interface. The memory portion may include at least one semiconductor package, as discussed above.

Example embodiments provide that the filler may be formed of one of an inorganic material and an organic material, and the water absorption material may be formed of a water absorbing polymer.

Example embodiments provide that the connection portion may be one of soldering balls, a conductive bump, and a lead grid array (LGA).

Example embodiments provide that the controller portion and the memory portion may each include a plurality of semiconductor packages stacked on one another.

### BRIEF DESCRIPTION OF THE DRAWINGS

The above and other features and advantages will become more apparent by describing in detail example embodiments of the inventive concepts with reference to the attached drawings. The accompanying drawings are intended to depict example embodiments of the inventive concepts and should not be interpreted to limit the intended scope of the claims. The accompanying drawings are not to be considered as drawn to scale unless explicitly noted.

FIG. 1 is a schematic cross-sectional view of a semiconductor package, according to an example embodiment of inventive concepts;

FIG. 2 is a flowchart illustrating a method of fabricating a molding composition for a semiconductor package, according to an example embodiment of inventive concepts;

FIG. 3 is a cross-sectional view of main components of an integrated circuit (IC) device, according an example embodiment of inventive concepts;

FIG. 4 is a plan view of main components of an IC device, according to an example embodiment of inventive concepts;

FIG. 5 is a diagram of main components of an IC system, according to an example embodiment of inventive concepts; and

FIG. 6 illustrates a mobile wireless phone according to an example embodiment of inventive concepts.

### DETAILED DESCRIPTION OF EXAMPLE EMBODIMENTS

Hereinafter, the inventive concepts will be described more fully with reference to the accompanying drawings, in which example embodiments of inventive concepts are shown.

These inventive concepts may be embodied in many different forms and should not be construed as limited to the example embodiments set forth herein. Rather, these example embodiments are provided so that this disclosure will be thorough and complete, and will fully convey the scope of the inventive concept to those skilled in the art.

It will be understood that, although the terms ‘first’, ‘second’, ‘third’, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of inventive concepts. For example, a first element may be designated as a second element, and similarly, a second element may be designated as a first element without departing from the teachings of inventive concepts.

Unless otherwise defined, all terms (including technical and scientific terms) used herein have the same meaning as commonly understood by one of ordinary skill in the art to which these inventive concepts belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein. As used herein, the term “and/or” includes any and all combinations of one or more of the associated listed items. Expressions such as “at least one of,” when preceding a list of elements, modify the entire list of elements and do not modify the individual elements of the list.

It will be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Spatially relative terms, such as “below”, “beneath”, “lower”, “above”, “upper”, and the like, may be used herein for ease of description to describe the relationship of one element or feature to another element(s) or feature(s) as illustrated in the figures. It will be understood that the spatially relative terms are intended to encompass different orientations of the device in use or operation, in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

If an embodiment is differently realizable, a specified operation order may be differently performed from a described order. For example, two consecutive operations may be substantially simultaneously performed, or in an order opposite to the described order.

Variations from the shapes of the illustrations as a result, for example, of manufacturing techniques and/or tolerances, are to be expected. Thus, embodiments of inventive concepts should not be construed as limited to the particular shapes of regions illustrated herein but are to include deviations in shapes that result, for example, from manufacturing.

Reference will now be made in detail to embodiments, examples of which are illustrated in the accompanying drawings, wherein like reference numerals refer to like elements throughout. In the drawings, the thicknesses of layers and regions are exaggerated for clarity. It will also be understood that when a layer is referred to as being “on” another layer or substrate, it can be directly on the other layer or substrate, or intervening layers may also be present.

The molding composition according to example embodiments of inventive concepts includes a molding resin material, a filler dispersed in the molding resin material, and a water absorption material adsorbed and/or coated on a surface of the filler. According to example embodiments, the water absorption material is adsorbed and/or coated on the surface of the filler so as to cover at least a part of an outer surface of the filler.

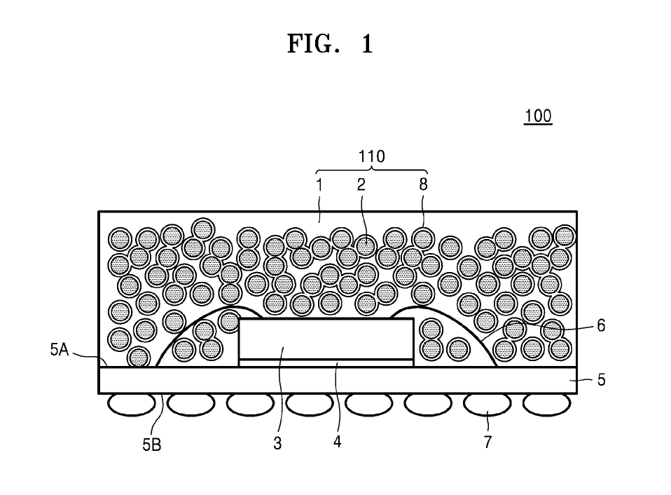

FIG. 1 is a schematic cross-sectional view of a semiconductor package 100, according to an example embodiment of inventive concepts. The semiconductor package 100 includes a substrate 5, a die attach film 4 disposed on the substrate 5, a chip 3 disposed on the substrate 5 and attached to the substrate 5 through the die attach film 4, a connecting portion 6 (e.g., bonding wires, solder balls, solder bumps, and/or any other known bonding technique) for electrically connecting the chip 3 and the substrate 5, and a molding portion 110 encapsulating the chip 3 and the connecting portion 6 and protecting a mounting structure including the substrate 5, the chip 3 mounted on the substrate 5, and the connecting portion 6. A plurality of soldering balls 7 for electrically connecting the chip 3 and an external circuit (not shown) are formed on a surface 5B opposite to a mounting surface 5A of the substrate 5 where the chip 3 is mounted. It should be noted that although example embodiments describe electrically connecting the chip 3 and an external circuit is by way of a plurality of soldering balls 7, example embodiments are not limited thereto. For example, chip 3 may be electrically connected to an external circuit by way of a conductive bump, a lead grid array (LGA), and the like.

The molding portion 110 may be formed to completely cover the chip 3 and the connecting portion 6 on the substrate 5. The molding portion 110 is obtained from a molding composition, according to various example embodiments of inventive concepts. The molding composition includes a molding resin material 1, a filler 2 dispersed in the molding resin material 1, and a water absorption material 8 adsorbed and/or coated on a surface of the filler 2. According to various embodiments, filler 2 may be a filler material (or combination of materials) that includes a plurality of filler particles. According to an example embodiment, the water absorption material 8 may be coated on the surfaces of the filler 2 (or the filler particles) so as to cover at least a part of an outer surface of each of the filler 2 (or filler particles). Herein, the term “molding composition” denotes a material forming at least a part of the molding portion 110, and the terms “molding composition” and a “molding material” have the same meaning, and thus, may be used interchangeably. The molding resin material 1 included in the molding portion 110 may be formed of epoxy resin that is used for semiconductor encapsulation. According to various embodiments, any type of epoxy resin may be used. Examples of the epoxy resin that may be used as the molding resin material 1 include biphenyl epoxy resin, novolac epoxy resin, dicyclopentadienyl epoxy resin, bisphenol epoxy resin, terpene epoxy resin, aralkyl epoxy resin, multi-functional epoxy resin, naphthalene epoxy resin, and halogenated epoxy resin. The aforementioned epoxy resin types may be used alone or in combination using two or more epoxy resin types. According to an example embodiment, the molding resin material 1 may be formed of a material including at least one additive selected from among a curing agent, a curing accelerator, a reaction adjusting agent, a release agent, a coupling agent, a stress relaxant, and a subsidiary flame retardant in addition to the epoxy resin. It should be noted that according to example embodiments of inventive concepts, the materials forming the molding resin material 1 are not limited to above, and the molding resin material 1 may be selected from various materials or a combination of various materials.

Filler 2 included in the molding portion 110 may be formed of an inorganic material, an organic material, or a combination thereof. When the filler 2 includes an inorganic material, the inorganic material forming the filler 2 may include at least one of silicon oxide, silicon dioxide, calcium carbonate, magnesium carbonate, magnesia, clay, alumina (Al₂O₃), titania (TiO₂), talc, calcium silicate, antimony oxide, glass fiber, and eucryptite ceramic. The eucryptite ceramic may be a crystallization glass formed of Li₂O, Al₂O₃, and SiO₂. When the plurality of filler 2 include an organic material, the organic material forming the filler 2 may include at least one of polyethyleneimine, ethyleneglycol, and polyethyleneglycol. It should be noted that according to example embodiments of inventive concepts, the materials forming the filler 2 are not limited to above, and the filler 2 may be selected from various materials and/or a combination of various materials.

According to an example embodiment, the plurality of filler 2 may be included in a range higher than 5 wt % and lower than 80 wt % based on a weight of the molding resin material 1, but embodiments of inventive concepts are not limited thereto. An amount of the filler 2 included in the molding portion 110 may be suitably adjusted according to desired properties, such as moldability, a low stress property, and high-temperature strength.

The water absorption material 8 may be selected from various materials. According to an example embodiment, the water absorption material 8 may be formed of a material having a water absorbing property, and may include at least one of a synthetic-resin-based material, a cellulose-based material, and a starch-based material.

According to an example embodiment, the water absorption material 8 may be formed of water absorbing polymers. For example, the water absorption material 8 may include at least one synthetic resin-based material selected from among polyacrylate based polymer, polyvinyl alcohol based polymer, vinyl acetate copolymer, and polyacrylonitrile hydrolyzate.

According to another example embodiment, the water absorption material 8 may include at least one cellulose-based material selected from among carboxymethyl cellulose, carboxyethyl cellulose, and hydroxypropyl cellulose.

According to another example embodiment, the water absorption material 8 may include at least one starch-based material selected from among hydrolyzed acrylonitrile grafted starch and acrylic acid grafted starch.

According to an example embodiment, the water absorption material 8 may be coated on the surface of each of the filler 2 in a thickness less than about 5 μm. For example, the water absorption material 8 may have a thickness from about 1 to about 2 μm, but the thickness of the water absorption material 8 is not limited thereto. The water absorption material 8 covering the filler 2 may have different thicknesses according to locations on the surfaces of the filler 2. For example, the water absorption material 8 may have portions having a thickness less than about 5 μm, and portions having a thickness equal to or higher than about 5 μm.

The water absorption material 8 absorbs moisture penetrated into the semiconductor package 10 from outside the semiconductor package 100, and traps the absorbed moisture so as to maintain a dry state of the chip 3 and a region around the chip 3. According to an example embodiment, the water absorption material 8 may trap moisture via a hydrogen bond with water molecules having a volume of approximately 500 times a volume of the water absorption material 8. Accordingly, the moisture penetrated into the semiconductor package 100 may be absorbed in the water absorption material 8 that is coated on the surface of the filler 2 (or the surfaces of the filler particles) instead of moving to the chip 3, and thus the region around the chip may maintain a dry state. Accordingly, even when a defect, such as a void, exists below the chip 3, a delamination phenomenon between the layers of the semiconductor package 100 (e.g., between the chip 3, the die attach film 4, the substrate 5, and/or the connecting portion 6) may be prevented from occurring in the semiconductor package 100 due to moisture concentration and/or accumulation.

In the semiconductor package 100 according to one or more example embodiments of inventive concepts, by adsorbing and/or coating the surface of the filler 2 (or the surface of each of the filler particles) included in the molding portion 110 with the water absorption material 8, stability and reliability of the chip 3 may be maintained since external moisture is absorbed by the water absorption material 8 coated on the surface of the filler 2 (or the surfaces of the filler particles), and thus an amount of external moisture penetrating into the semiconductor package 100 may be diminished or reduced.

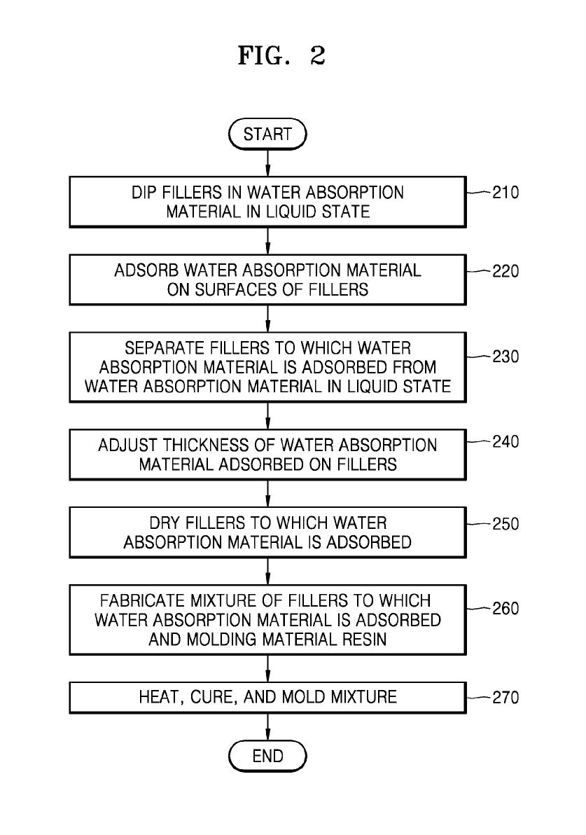

FIG. 2 is a flowchart illustrating a method of fabricating a molding composition for a semiconductor package, according to an example embodiment of inventive concepts.

As shown in operation 210, a filler is dipped in a water absorption material in a liquid state. As used herein, the terms “filler”, “fillers”, and “filler material” have the same meaning and may be used interchangeably. Additionally, the term “filler particles” denotes a material comprising at least a part of the filler and/or filler material, and thus, the terms “filler”, “filler material”, and “filler particles” have the same meaning and may be used interchangeably. The filler may include at least one material described above with reference to filler 2 of FIG. 1. Furthermore, the water absorption material in the liquid state may include at least one material described above with reference to water absorption material 8 of FIG. 1.

As shown in operation 220, the water absorption material is adsorbed on the surfaces of the filler. According to various embodiments, the filler may be a filler material that includes a plurality of filler particles, such that the water absorption material may be adsorbed and/or coated on the surfaces of filler particles while the filler material is dipped in the water absorption material in the liquid state. It should be noted that depending upon the composition of the filler and/or filler particles, the water absorption material may be absorbed by the filler particles while the filler particles are dipped in the water absorption material in the liquid state. According to an example embodiment, the water absorption material in the liquid state may be stirred in order for the water absorption material to uniformly adsorb and/or coat on the surfaces of the filler.

As shown in operation 230, the filler to which the water absorption material is adsorbed are separated from the water absorption material in the liquid state.

As shown in operation 240, a thickness of the water absorption material adsorbed on the filler is adjusted. According to an example embodiment, in order to adjust the thickness of the water absorption material, the filler to which the water absorption material is adsorbed may be inserted or otherwise placed in a centrifuge that is configured to rotate the filler, thereby reducing the thickness of the water absorption material on the surfaces of the filler and/or filler particles. According to another example embodiment, when the filler and/or filler particles are rotated in the centrifuge, a relatively thin thickness of the water absorption material on the surface of the filler may be increased, or a region of the surface of the filler that was not coated by the water absorption material may be coated by the water absorption material. According to an example embodiment, the centrifuge may be controlled such that the water absorption material having a thickness less than or equal to about 5 μm is left on the surface of the filler and/or filler particles. For example, the water absorption material having a thickness from about 1 to about 2 μm may be left on the surface of the filler and/or filler particles.

As shown in operation 250, the filler to which the water absorption material is adsorbed are dried.

As shown in operation 260, a mixture of the dried filler to which the water absorption material is adsorbed and a molding resin material is fabricated.

As shown in operation 270, the mixture is heated, cured, and molded to fabricate a molding composition suitable for a semiconductor package. According to an example embodiment, the molding composition may be fabricated by uniformly mixing components required for the molding composition by using a Henschel mixer or a Redige mixer. The mixture may be melted and mixed at 90° C. to 120° C. by using a roll mill or a kneader, and then cooling and pulverizing the molten mixture.

In order to fabricate a semiconductor package, such as the semiconductor package 100 of FIG. 1, by using the molding composition, a process of forming the molding portion 110 that encapsulates the chip 3 mounted on the substrate 5 may be performed via a low pressure transfer molding process. However, example embodiments of inventive concepts are not limited thereto, and an injection molding process or a casting process may be used instead of the low pressure transfer molding process.

According to example embodiments of inventive concepts, the molding composition may protect the chip region in the semiconductor package from moisture concentration and/or accumulation, thereby improving reliability of the semiconductor package under moist conditions and/or environments.

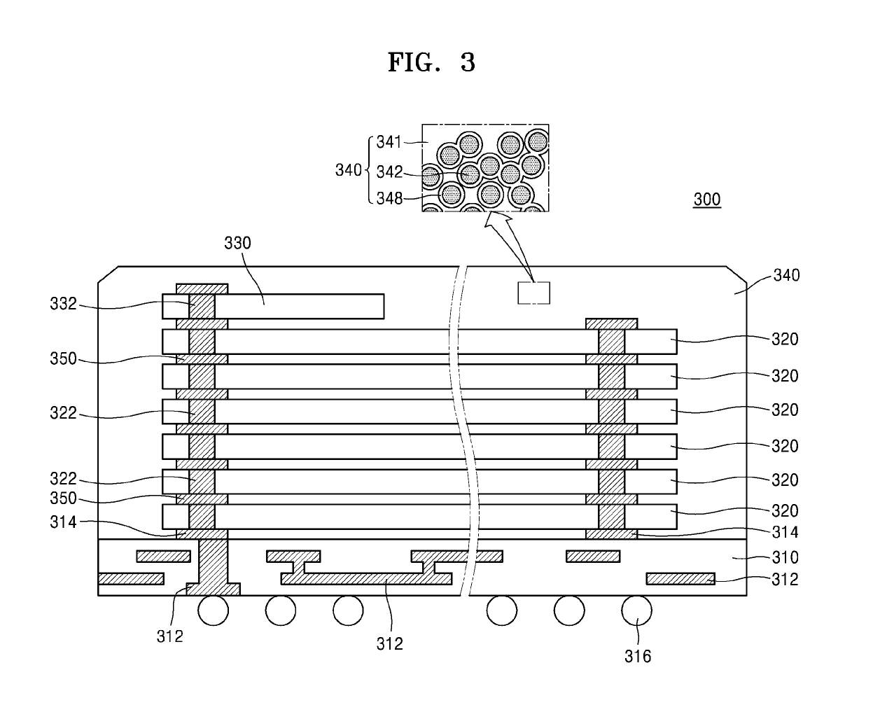

FIG. 3 is a cross-sectional view of main components of an integrated circuit (IC) device 300, according an example embodiment of inventive concepts.

Referring to FIG. 3, the IC device 300 includes a plurality of semiconductor chips 320 sequentially stacked on a package substrate 310. A control chip 330 is connected on the semiconductor chips 320. A stacked structure of the semiconductor chips 320 and the control chip 330 is encapsulated by a molding portion 340 on the package substrate 310. The molding portion 340 may have a similar structure as the molding portion 110 described above with reference to FIG. 1. The molding portion 340 includes the molding composition according to example embodiments of inventive concepts. The molding composition includes a molding resin material 341, filler 342 dispersed in the molding resin material 341, and a water absorption material 348 coated on a surface of the filler 342. According to an example embodiment, the water absorption material 348 is coated on the surface of the filler 342 (or the filler particles that make up filler 342) so as to cover at least a part of an outer surface of the filler 342 (or an outer surface of each filler particle that makes up filler 342). The molding resin material 341, the filler 342, and the water absorption material 348, may be the same or similar to the molding resin material 1, the filler 2, and the water absorption material 8 as described above with reference to FIG. 1.

As shown in FIG. 3, six semiconductor chips 320 are vertically stacked on each other, but the number and a stacked direction of the semiconductor chips 320 are not limited thereto. For example, the number of the semiconductor chips 320 may be more than or less than six. By way of another example, the semiconductor chips 320 may be arranged on the package substrate 310 in a horizontal direction, or in a connecting structure where the semiconductor chips 320 are connected in both a vertical and a horizontal direction. According to an example embodiment, the control chip 330 may be omitted.

The package substrate 310 may be a flexible printed circuit board, a rigid printed circuit board, or a combination thereof. The package substrate 310 includes a substrate internal wire 312 and a connecting terminal 314. The connecting terminal 314 may be formed on one surface of the package substrate 310. A soldering ball 316 is formed on the other surface of the package substrate 310. The connecting terminal 314 may be electrically connected to the soldering ball 316 via the substrate internal wire 312.

According to an example embodiment, the soldering ball 316 may be replaced by a conductive bump or a lead grid array (LGA).

The semiconductor chips 320 and the control chip 330 include connecting structures 322 and 332, respectively. According to an example embodiment, the connecting structures 322 and 332 may have a through silicon via (TSV) contact structure.

The connecting structures 322 and 332 of the plurality of semiconductor chips 320 and the control chip 330 may be electrically connected to the connecting terminal 314 of the package substrate 310 through a connecting portion 350, such as a bump.

Each of the semiconductor chips 320 may include a system large-scale integration (LSI), a flash memory, a dynamic random access memory (DRAM), a static random access memory (SRAM), an electrically erasable and programmable read only memory (EEPROM), a phase change random access memory (PRAM), a magnetic random access memory (MRAM), or a resistive random access memory (RRAM). The control chip 330 may include logic circuits, such as serializer/deserializer (SER/DES) circuit.

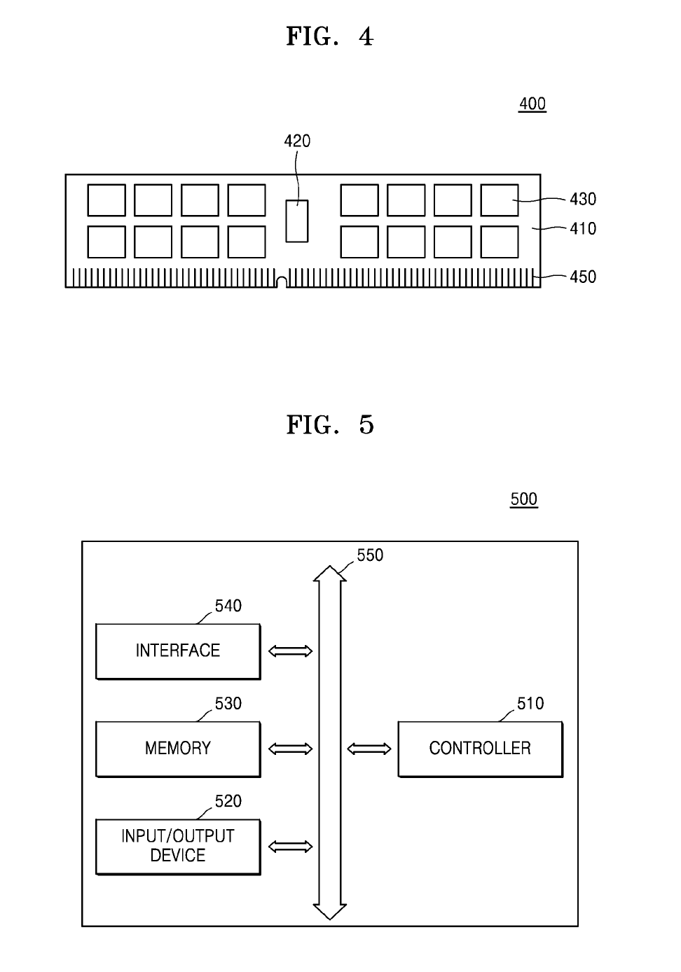

FIG. 4 is a plan view of main components of an IC device 400, according to an example embodiment of inventive concepts.

The IC device 400 includes a module substrate 410, a control chip 420 mounted on the module substrate 410, and a plurality of semiconductor packages 430. A plurality of input and output terminals 450 are formed at the module substrate 410. Furthermore, each of the plurality of semiconductor packages 430 may be the same or similar to semiconductor package 100 of FIG. 1. According to various embodiments, the plurality of semiconductor packages 430 may be replaced or substituted with a plurality of IC devices that are the same or similar to IC device 300 of FIG. 3.

The IC devices (e.g., IC device 300 and/or IC device 400) according to the one or more embodiments described above may be implemented as any of a variety of package forms. For example, at least some elements of the IC devices may be mounted using packages, such as, Package on Package (PoP), Ball grid arrays (BGAs), Chip scale packages (CSPs), Plastic Leaded Chip Carrier (PLCC), Plastic Dual In-Line Package (PDIP), Die in Waffle Pack, Die in Wafer Form, Chip On Board (COB), Ceramic Dual In-Line Package (CERDIP), Plastic Metric Quad Flat Pack(MQFP), Thin Quad Flatpack (TQFP), Small Outline (SOIC), Shrink Small Outline Package (SSOP), Thin Small Outline (TSOP), Thin Quad Flatpack (TQFP), System In Package (SIP), Multi Chip Package (MCP), Wafer-level Fabricated Package (WFP), and Wafer-Level Processed Stack Package (WSP).

FIG. 5 is a diagram of main components of an IC system 500, according to an example embodiment of inventive concepts.

The IC system 500 includes a controller 510, an input/output device 520, a memory 530, and an interface 540. The IC system 500 may be a mobile system or a system for receiving or transmitting information. According to an embodiment, the mobile system may be included with at least one of a personal digital assistant (PDA), a mobile computer, a tablet personal computer, a wireless or mobile phone, a digital music player, and a memory card.

According to an example embodiment, the controller 510 may be a microprocessor, a digital signal processor, or a micro-controller.

The input/output device 520 is used for data input and output of the IC system 500. The IC system 500 may be connected to an external device, such as a personal computer or a network, by using the input/output device 520, and may exchange data with the external device. According to an example embodiment, the input/output device 520 is a keypad, a keyboard, a display, or a touchscreen display.

According to an example embodiment, the memory 530 stores program code and/or data for operating the controller 510. According to another example embodiment, the memory 530 stores data processed by the controller 510. At least one of the controller 510 and the memory 530 may be the same or similar to the IC device 300 of FIG. 3 and/or the IC device 400 of FIG. 4, and may include at least one of the semiconductor package 100 of FIG. 1.

The interface 540 operates as a data transmission path between the computing device 500 and one or more external devices. In various embodiments, the interface 540 may include a wireless transceiver configured to operate in accordance with the IEEE 802.11-2007 standard (802.11) or other like wireless standards in order to communicate with the one or more external devices. The controller 510, the input/output device 520, the memory 530, and the interface 540 may communicate with each other through a bus 550.

The IC system 500 may be included in or otherwise associated with a mobile phone, a tablet personal computer, an MP3 player, a navigation system, a portable multimedia player (PMP), a solid state disk (SSD), a household appliance, or other like devices.

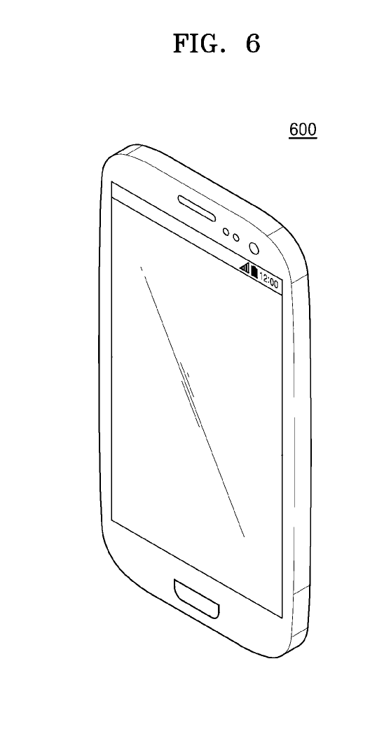

FIG. 6 illustrates a mobile wireless phone 600 according to example embodiments of inventive concepts. According to various embodiments, the mobile wireless phone 600 may include an IC system that is the same or similar to IC system 500 of FIG. 5. Mobile wireless phone 600 may include at least one of the semiconductor package 100 of FIG. 1, the IC device 300 of FIG. 3, and the IC device 400 of FIG. 4. Furthermore, in alternate embodiments, mobile wireless phone 600 may be one of a tablet personal computer, an MP3 player, a navigation system, a portable multimedia player (PMP), a solid state disk (SSD), a household appliance, or other like device.

While inventive concepts have been particularly shown and described with reference to example embodiments thereof, it will be understood that various changes in form and details may be made therein without departing from the spirit and scope of the following claims.

What is claimed is:

1. A molding material for a semiconductor package, comprising:
a molding resin material;
a filler in the molding resin material; and
a water absorption material coated on an outer surface of the filler.

2. The molding material of claim 1, wherein the water absorption material is a water absorbing polymer resin.

3. The molding material of claim 1, wherein the water absorption material is a water absorbing polymer including one of a polyacrylate based polymer, a polyvinyl alcohol based polymer, a vinyl acetate copolymer, and a polyacrylonitrile hydrolyzate.

4. The molding material of claim 1, wherein the filler comprises silicon dioxide particles.

5. The molding material of claim 1, wherein the molding resin material comprises an epoxy resin.

6. The molding material of claim 1, wherein a thickness of the water absorption material is less than 5 micrometers (μm).

7. A method of fabricating a molding material for a semiconductor package, the method comprising:
dipping a filler in a water absorption material that is in a liquid state;
removing the filler from the water absorption material after the water absorption material is adsorbed on a surface of the filler;
controlling a thickness of the water absorption material adsorbed on the surface of the filler; and
drying the water absorption material adsorbed on the surface of the filler.

8. The method of claim 7, wherein controlling the thickness of the water absorption material includes inserting the filler into a centrifuge and rotating the centrifuge until a desired thickness is obtained.

9. The method of claim 7, wherein the molding material is heated, cured, and molded to form the molding material to a semiconductor package.

10. A semiconductor package, comprising:
a substrate;
a die attach film on the substrate;
at least one chip on the substrate and attached to the substrate through the die attach film;
a connecting portion electrically connecting the chip and the substrate;
the molding material of claim 1; and
a connection portion electrically connecting the semiconductor package with an external circuit.

11. The semiconductor package of claim 10, wherein the filler comprises silicon dioxide particles.

12. The semiconductor package of claim 10, wherein the molding material encapsulates at least one of the connecting portion and the connection portion.

13. The semiconductor package of claim 10, wherein the connecting portion includes bonding wires and the connection portion includes soldering balls.
